(19) United States
(12) Patent Application Publication
(10) Pub. No.: US 2016/0314939 A1
(43) Pub. Date: Oct. 27, 2016

(54) Plasma-resistant Aluminum Oxynitride Based Reactor Components for Semi-Conductor Manufacturing and Processing Equipment

(71) Applicant: Surmet Corporation, Burlington, MA (US)

(72) Inventors: Suri A Sastri, Lexington, MA (US); Mohan babu Ramisetty, Burlington, MA (US)

(21) Appl. No.: 15/136,944

(22) Filed: Apr. 24, 2016

Related U.S. Application Data
(60) Provisional application No. 62/152,556, filed on Apr. 24, 2015.

(51) Int. Cl. H01J 37/32; H01L 21/3065; H01L 21/285; H01L 21/3213; H01L 21/02; H01L 21/67; H01L 21/311

(52) U.S. Cl. CPC H01J 37/32467; H01L 21/67069; H01L 21/3065; H01L 21/31116; H01L 21/31138; H01L 21/32136; H01L 21/02274; H01L 21/0262; H01L 21/28556; H01J 37/32495; H01J 37/32715; H01J 37/32119; H01J 2237/332; H01J 2237/327; H01J 2237/334

(57) ABSTRACT

An aluminum oxynitride-based plasma reactor for processing of semiconductor substrates is provided. A method for making an aluminum oxynitride reactor components is also provided. A method for processing a semiconductor substrate in an aluminum oxynitride based plasma reactor is also provided.

### RELATED APPLICATIONS

This application claims benefit of and priority to U.S. Provisional Application Ser. No. 62/152,556 filed Apr. 24, 2015 under 35 U.S.C. §§119, 120, 363, 365, and 37 C.F.R. §1.55 and §1.78 and incorporated herein by this reference.

### FIELD OF THE INVENTION

The invention relates to an aluminum oxynitride based plasma reactor for a semiconductor manufacturing process. The plasma reactor, having a reactor chamber that is capable of being evacuated, includes a chamber wall and has been provided with a gas inlet and a gas outlet and which comprises a holding, heating or processing apparatus for a substrate or an object or part to be processed, wherein at least one component of the reactor is made from a polycrystalline aluminum oxynitride (AlON) based bulk material.

### BACKGROUND OF THE INVENTION

In the field of semiconductor processing, vacuum processing plasma reactors are generally used for etching and chemical vapor depositing (CVD) of materials on substrates by supplying an etching or deposition gas to the vacuum chamber and application of an RF field to the gas to energize the gas into a plasma state. Examples of such plasma chambers include parallel plate, transformer coupled plasma (TCP™) also known as inductively coupled plasma (ICP), and electron-cyclotron resonance (ECR) reactors and components thereof. Because of the corrosive nature of the plasma environment in such reactors, and the requirement for minimizing particle and/or heavy metal contamination, it is highly desirable for the components of such equipment to exhibit high corrosion resistance.

Plasmas are used to remove materials by etching or for deposition of materials on substrates. The plasma etch conditions create significant ion bombardment of the surfaces of the processing chamber and other components that are exposed to the plasma. This ion bombardment, combined with plasma chemistries and/or etch byproducts, can produce significant erosion, corrosion and corrosion-erosion of the plasma-exposed surfaces of the processing chamber. As a result, the surface materials are removed by physical and/or chemical attack, including erosion, corrosion and/or corrosion-erosion. This attack causes problems including short part-lifetimes, increased consumable costs, particulate contamination, on-wafer transition metal contamination and process drift.

During processing of semiconductor substrates, the substrates are typically held in place within the vacuum chamber by substrate holders such as electrostatic clamps. Process gas can be supplied to the chamber in various ways such as by a gas distribution plate. In addition to the plasma chamber equipment, other equipment used in processing semiconductor substrates include transport mechanisms, gas supply systems, liners, lift mechanisms, load locks, door mechanisms, robotic arms, fasteners, and the like. Various components of such equipment are subject to corrosive conditions associated with semiconductor processing.

Further, in view of increasing data processing speed and miniaturization requirements, usage of high density plasma for high etch rate and consequently the high purity requirements for processing semiconductor substrates such as silicon wafers and dielectric materials such as the glass substrates used for flat panel displays, components having improved corrosion resistance are highly desirable in such environments.

As integrated circuit devices continue to shrink in both their physical size and their operating voltages, their associated manufacturing yields become more susceptible to particle and metallic impurity contamination. Consequently, fabricating integrated circuit devices having smaller physical sizes requires that the level of particulate and metal contamination be less than previously considered to be acceptable. Furthermore, there is a need for components of high density plasma processing apparatus composed of materials that provide improved resistance to physical and chemical attack, including erosion, corrosion and/or erosion-corrosion, to minimize the associated contamination of semiconductor materials during their processing. Materials that can increase the service life of components of the equipment and thus reduce the down time of the apparatus, would contribute to reducing the cost of processing semiconductor materials.

One of the most commonly practiced approaches to provide resistance to plasma erosion, corrosion and/or corrosion-erosion to semiconductor processing apparatus and components thereof is to apply a plasma resistant coating on the surfaces that are exposed to plasma. Such ceramic coatings are yttria, ceria, aluminum oxide and aluminum oxynitride on commonly used bulk materials such as quartz, aluminum, aluminum-alloy, and other ceramics and metals. These coating are known to be effective in decreasing the erosion and/or corrosion-erosion rate of the underlying substrate materials; however, as density and intensity of plasma keep climbing in order to keep up with the ever-increasing demand for miniaturization and faster etch rates in the semiconductor industry, coatings cannot provide sufficient resistance to plasma erosion and/or corrosion-erosion. Furthermore, as disclosed in U.S. patent application Ser. No. 14/234,023, rate of etching data for aluminum oxynitride and yttria based coatings on quartz and aluminum-alloy substrates, suggest that even a 100 microns thick coating will not last more than 200 hrs of plasma exposure and coating life time could even be lower in the case of exposure to high density plasma.

### SUMMARY OF THE INVENTION

In light of the problems and prior art noted above in the Background section, the present invention offers an effective solution by providing a plasma-resistant aluminum oxynitride based component of a semiconductor manufacturing apparatus such as plasma processing reactor used for semiconductor manufacturing process.

Featured is a plasma reactor having an evacuable reactor chamber, which has a chamber wall and has been provided with a gas inlet and a gas outlet and which comprises a holding, heating or processing apparatus for a part or substrate to be processed, wherein at least one component of the chamber wall or of the holding and heating or processing apparatus is designed from polycrystalline AlON based bulk material. Such components can also include chamber wall liners, substrate supports, gas distribution systems (including showerheads, baffles, rings, nozzles, etc.), fasteners, heating elements, electrostatic clamps, plasma screens, liners, transport module components, such as robotic arms, fasteners, inner and outer chamber walls, dielectric windows, and the like.

Also featured is a method of making an AlON based plasma reactor components for use in semiconductor manufacturing process. The method may include synthesis of AlON powder, milling/mixing of powder with binders, formation of AlON green bodies by consolidation of powder or colloidal filtration or plastic forming techniques followed by heat treatment for densification.

Also featured is a method of processing a semiconductor substrate in a plasma reactor having an evacuable chamber, which has a chamber wall and has been provided with a gas inlet and a gas outlet and which comprises a holding, heating or processing device, wherein at least one component of the reactor is made from an AlON based material. The method may include loading a semiconductor substrate into the reactor chamber, evacuating the chamber, introducing a process gas into the reactor, exposing the surface of the substrate to the plasma and/or gas for etching or deposition or processing.

The subject invention in other embodiments, need not achieve all these objectives and the claims hereof should not be limited to structures or methods capable of achieving these objectives.

### BRIEF DESCRIPTION OF THE SEVERAL VIEWS OF THE DRAWINGS

Other objects, features and advantages will occur to those skilled in the art from the following description of a preferred embodiment and the accompanying drawings, in which:

FIG. 1 is schematic view of one embodiment of a reactor for a plasma-assisted semiconductor manufacturing process having a chamber wall, holding device and a dielectric window.

FIG. 2 is schematic views of examples of reactor components made from AlON based material.

### DETAILED DESCRIPTION OF THE INVENTION

Aside from the preferred embodiment or embodiments disclosed below, this invention is capable of other embodiments and of being practiced or being carried out in various ways. Thus, it is to be understood that the invention is not limited in its application to the details of construction and the arrangements of components set forth in the following description or illustrated in the drawings. If only one embodiment is described herein, the claims hereof are not to be limited to that embodiment. Moreover, the claims hereof are not to be read restrictively unless there is clear and convincing evidence manifesting a certain exclusion, restriction, or disclaimer.

Featured is a plasma reactor having an evacuable reactor chamber, which has a chamber wall and has been provided with a gas inlet and a gas outlet and which comprises a holding, heating or processing device for a part or object to be processed, wherein at least one component of the chamber wall or of the holding and heating or processing device is designed from polycrystalline AlON based bulk material. Such components can also include chamber wall liners, substrate supports, gas distribution systems (including showerheads, baffles, rings, nozzles, etc.), fasteners, heating elements, electrostatic clamps, plasma screens, liners, transport module components, such as robotic arms, fasteners, inner and outer chamber walls, dielectric windows, etc., and the like.

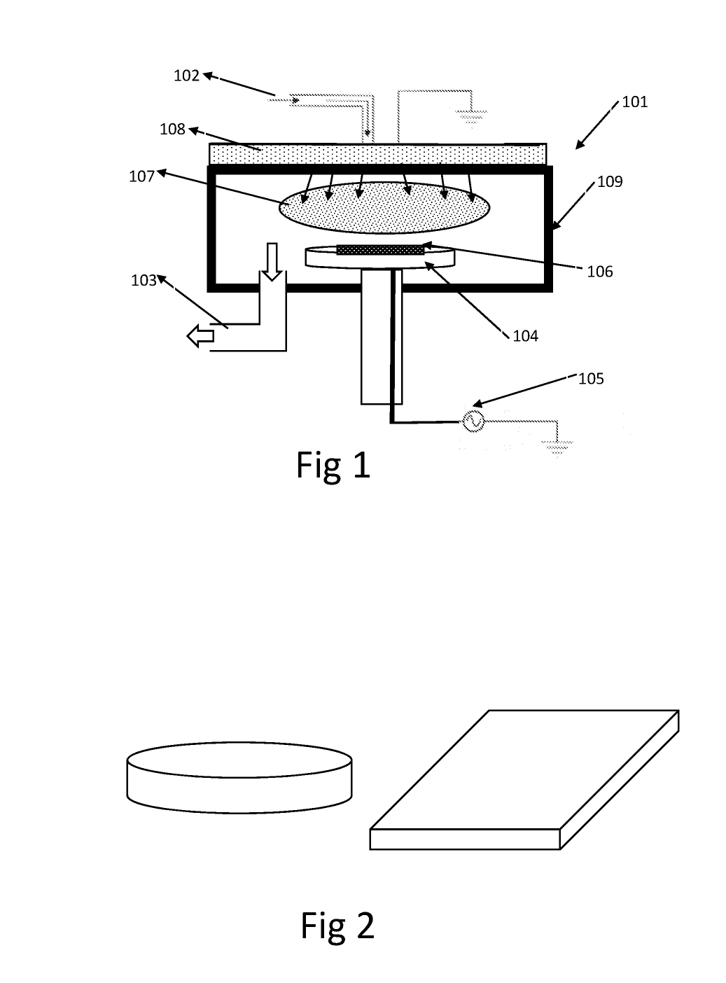

An example schematic view of a typical plasma reactor in illustrated in FIG. 1. The reactor 101 has a gas inlet 102 and a gas outlet or a pump port 103, an AlON-based holding chuck 104 to hold a wafer or a semiconductor substrate 106 which is to be processed, RF power supply 105 to energize gas and generate plasma 107, an AlON-based dielectric window 108 and AlON-based chamber walls 109. FIG. 2 illustrates example shapes of AlON components used in the reactor according to present invention.

In certain embodiments, components of the reactor may be designed such that the bulk of the components is made from different materials such as aluminum oxide, quartz, aluminum, and the surfaces of the components that are exposed to plasma can be made from AlON based material, for example, in the form of liners, to exploit AlON's plasma resistance.

Also featured is a method of making an AlON based component of a plasma reactor for use in semiconductor manufacturing process. The method may include synthesis of AlON powder, milling/mixing of powder, taking the milled substantially pure AlON powders or slurry and adding a binder to the slurry, the slurry is then screened and spray dried to form a precursor. The precursor, a spray dried powder, is then screened to remove large granules and chunks. The screened precursor is filled into a mold and isostatically pressed to form a green article having a desired shape or to a blank, which then can be machined to desired shape and size. Alternatively, green bodies can be made by using colloidal filtration or plastic forming or injection molding techniques. The green article is then heated slowly to remove the binder and other additives, and then sintered to about 96 to 99% density relative to theoretical density to achieve closed porosity. Optionally, the sintered article is then hot isostatically pressed (HIP) to further densify it to greater than 99% of its theoretical density. In certain embodiments, components of the reactor according to the present invention can be machined to the desired size and shape after the heat treatment. For example, holes in a dielectric window of the reactor can be machined after the heat treatment.

Also featured is a method of processing a semiconductor substrate in the reactor according to the present invention. The method may include loading or transferring the semiconductor substrate into the plasma chamber according to the present invention and an exposed surface of the substrate is processed with a plasma. In certain embodiments, the method may include positioning the substrate on a substrate support in the reactor, introducing a process gas into the reactor, applying RF energy to the process gas to generate a plasma adjacent to the exposed surface of the substrate and etching or otherwise processing the exposed substrate surface with a plasma.

In certain embodiments, the method may include etching features into an etch layer in the reactor according to the present invention. The method may comprise plurality of cycles. Each cycle comprises a deposition phase and an etching phase. The deposition phase comprises providing a flow of deposition gas, forming a plasma from the deposition gas in the plasma processing chamber, providing a first bias during the deposition phase to provide an anisotropic deposition, and stopping the flow of the deposition gas into the plasma processing chamber. The etching phase, comprises providing a flow of an etch gas, forming a plasma from the etch gas in the plasma processing chamber, providing a second bias during the etch phase, wherein the first bias is greater than the second bias, and stopping the flow of the etch gas into the plasma processing chamber.

AlON components in the reactor according to present invention can also be transparent to light in the UV, visible and infrared wavelengths.

Although specific features of the invention are shown in some drawings and not in others, this is for convenience only as each feature may be combined with any or all of the other features in accordance with the invention. The words “including”, “comprising”, “having”, and “with” as used herein are to be interpreted broadly and comprehensively and are not limited to any physical interconnection. Moreover, any embodiments disclosed in the subject application are not to be taken as the only possible embodiments.

In addition, any amendment presented during the prosecution of the patent application for this patent is not a disclaimer of any claim element presented in the application as filed: those skilled in the art cannot reasonably be expected to draft a claim that would literally encompass all possible equivalents, many equivalents will be unforeseeable at the time of the amendment and are beyond a fair interpretation of what is to be surrendered (if anything), the rationale underlying the amendment may bear no more than a tangential relation to many equivalents, and/or there are many other reasons the applicant can not be expected to describe certain insubstantial substitutes for any claim element amended.

Other embodiments will occur to those skilled in the art and are within the following claims.

What is claimed is:

1. An aluminum oxynitride-based plasma reactor for semiconductor manufacturing process, having an evacuable reactor chamber which comprises chamber walls, a gas inlet and a gas outlet, a dielectric window and a holding, heating or processing apparatus to hold, heat or process a semiconductor substrate.

2. The aluminum oxynitride-based plasma reactor of claim 1, wherein at least one component of the said reactor chamber, chamber walls or of the holding, heating and processing apparatus is made from polycrystalline aluminum oxynitride-based bulk material.

3. The aluminum oxynitride-based plasma reactor of claim 1, wherein a dielectric window is made from polycrystalline aluminum oxynitride-based bulk material

4. The aluminum oxynitride-based plasma reactor components of claim 2, in which the aluminum oxynitride components having greater than 99% of theoretical density.

5. The aluminum oxynitride-based plasma reactor according to claim 1, in which the plasma reactor is a parallel plate plasma reactor or a transformer coupled plasma reactor or an inductively coupled plasma (ICP) reactor or an electron-cyclotron resonance plasma reactor.

6. The aluminum oxynitride-based plasma reactor components of claim 2, in which the bulk material of the components is made from a different material and the plasma exposed surfaces comprise aluminum oxynitride lining.

7. The aluminum oxynitride-based plasma reactor components of claim 2, further comprising a plasma-resistant coating.

8. A method of making an aluminum oxynitride-based plasma reactor component, the method comprising:
a. Synthesis of aluminum oxynitride powder from high purity precursor materials
b. Milling or mixing of powder with binders
c. Formation of AlON reactor component green bodies by consolidation of powder or colloidal filtration or plastic forming techniques
d. And heat treating the said components for densification to greater than 99% of theoretical density

9. The method of claim 8, further comprising a step of machining or fabrication

10. The method of claim 8, in which the aluminum oxynitride powder having a cubic spinel crystal structure

11. A method of processing a semiconductor substrate in an aluminum oxynitride-based plasma reactor, the method comprising:
a. Loading the substrate into the aluminum oxynitride-based plasma reactor chamber
b. Evacuating the chamber
c. Introducing a process gas into the chamber
d. Applying RF energy to the process gas to generate a plasma
e. Exposing the surface of the substrate to the plasma and/or gas for etching or deposition or processing.

12. The method of claim 11, wherein the processing gas is selected from the group consisting of Cl₂, HBr, CF₄, CH₂F₂, O₂, N₂, Ar, NO₂, SF₆ and NF₃.
